(19) United States
(12) Patent Application Publication
(10) Pub. No.: US 2013/0309048 A1
(43) Pub. Date: Nov. 21, 2013

(54) APPARATUS AND METHOD FOR TRANSPORTING WAFER-SHAPED ARTICLES

(71) Applicant: Andreas GLEISSNER, RADENTHEIN (AT)

(72) Inventor: Andreas GLEISSNER, RADENTHEIN (AT)

(73) Assignee: LAM RESEARCH AG, VILLACH (AT)

(21) Appl. No.: 13/472,860

(22) Filed: May 16, 2012

(51) Int. Cl. H01L 21/677

(52) U.S. Cl. 414/222.01; 414/806

(57) ABSTRACT

An apparatus for transporting a wafer-shaped article, comprises a holder configured to hold a wafer-shaped article of a predetermined diameter, attached to a robot arm that is horizontally movable, via a linkage. The holder is vertically movable relative to the distal end of the robot arm via the linkage from a retracted position to an extended position.

### BACKGROUND OF THE INVENTION

1. Field of the Invention

The invention relates generally to an apparatus and method for transporting wafer-shaped articles, such as semiconductor wafers, in which a wafer-shaped article is introduced into a process chamber.

2. Description of Related Art

Semiconductor wafers are subjected to various surface treatment processes such as etching, cleaning, polishing and material deposition. To accommodate such processes, a single wafer may be supported in relation to one or more treatment fluid nozzles by a chuck associated with a rotatable carrier, as is described for example in U.S. Pat. Nos. 4,903,717 and 5,513,668. Alternatively, a chuck in the form of a ring rotor adapted to support a wafer may be driven without physical contact through an active magnetic bearing, as is described for example in International Publication No. WO 2007/101764 and U.S. Pat. No. 6,485,531.

Such chucks are sometimes mounted in closed process chambers to contain the hazardous substances used for wafer processing, as well as to maintain a superatmospheric pressure for those processes requiring such a condition. Closed process chambers are provided with a door or cover to permit loading and unloading of wafers on the chuck inside the process chamber.

Wafers are conventionally loaded and unloaded from open process modules by wafer-handling robots, wherein the end effector of such robots grips the wafer by any of various techniques, such as edge contact only (ECO), as described for example in U.S. Pat. Nos. 5,022,695, 5,700,046, 5,955,858, 6,100,677, 6,491,330, or by application of the Bernoulli principle, as described for example in DE 19948572A1 and U.S. Pat. No. 7,100,954.

Typically wafers are loaded on top of a chuck in a closed chamber. In order to facilitate the transfer of the wafer from an end effector to the chuck, lifting pins are provided that help to lower a wafer from a higher position on an end effector to a lower position on a chuck.

However, conventional end effectors for loading and unloading wafers are ill-suited for use with chucks that are housed within a closed process chamber, unless the process chamber is provided with a relatively large door or cover that unnecessarily exposes the chamber ambient when it is opened during loading and unloading of wafers. Loading is especially a problem if the level of the opening in the closed chamber is lower than the level of the position of the wafer when held by the chuck.

### SUMMARY OF THE INVENTION

The present inventors have developed an improved apparatus and method for transporting wafer-shaped articles, in which a holder carrying a wafer-shaped article can pass horizontally through a relatively narrow process chamber door, and can thereafter transport the wafer-shaped article within the process chamber in a vertical direction, to bring the wafer-shaped article to a loading and unloading position.

The holder may have the form of a blade or a fork, on which the wafer rests. The wafer may rest on the blade via the wafer's lower side, or may contact the blade via its edge only, or its peripheral bevel region. The wafer may also be gripped by gripping pins of the holder, in which case the holder may be referred to as a gripper.

Thus, the invention in one aspect relates to an apparatus for transporting a wafer-shaped article, comprising a holder configured to hold a wafer-shaped article of a predetermined diameter, a robot arm that is horizontally movable, and a linkage interconnecting a distal end of the robot arm and the holder. The holder is vertically movable relative to the distal end of the robot arm via the linkage from a retracted position to an extended position.

In preferred embodiments of the apparatus according to the present invention, the distal end of the robot arm, the holder and the linkage collectively have a first vertical extent in the retracted position and a second vertical extent in the extended position, the second vertical extent being at least twice that of the first extent.

In preferred embodiments of the apparatus according to the present invention, the holder and the linkage constitute an end effector of a wafer transport robot.

In preferred embodiments of the apparatus according to the present invention, the end effector fits through an opening whose vertical clearance is less than 6 cm. Even more preferably, the end effector fits through an opening whose the vertical clearance is less than 3 cm.

In preferred embodiments of the apparatus according to the present invention, the linkage is a parallelogram linkage comprising at least two links. Advantageously, the apparatus is configured so that the vertical extent of the linkage beneath the wafer-shaped article as the wafer-shaped article is placed on the holder is less than 2 cm.

In preferred embodiments of the apparatus according to the present invention, a powered actuating element engages at least one of the at least two links, and is operable to pivot the link about one of its pivot pins so as to cause the holder to move from a collapsed entry position to an extended loading and unloading position.

In preferred embodiments of the apparatus according to the present invention, the powered actuating element comprises a pneumatic cylinder. Alternatively, the powered actuating element may be piezo-electrically driven.

In preferred embodiments of the apparatus according to the present invention, the powered actuating element is operable to move the holder vertically while the distal end of the robot arm remains stationary. It is particularly preferred that the robot arm remains stationary with respect to the vertical axis. However, if desired the robot arm may move horizontally in order to compensate the horizontal movement of the holder when it is vertically moved.

In preferred embodiments of the apparatus according to the present invention, the holder is designed to hold a wafer-shaped article by edge contact only.

In preferred embodiments of the apparatus according to the present invention, the holder is configured to hold a wafer-shaped article of a predetermined thickness, and wherein the linkage permits the holder to be moved vertically relative to the distal end of the robot arm by a distance that is at least 15 times greater than the predetermined thickness of the wafer-shaped article.

The present invention in another aspect relates to a method of transporting a wafer-shaped article, comprising positioning a wafer-shaped article on a holder of a robot arm, moving the robot arm so as to cause the holder to pass horizontally through a lateral opening in a process chamber, and displacing the holder vertically relative to the robot arm so as to bring the wafer-shaped article to a loading and unloading position.

In preferred embodiments of the method according to the present invention, the displacing is effected by a linkage interconnecting the holder and a distal end of the robot arm.

In preferred embodiments of the method according to the present invention, a powered actuating element mounted on the robot arm acts on the linkage to effect the displacing.

In preferred embodiments of the method according to the present invention, the lateral opening is greater than 30 cm in width and has a vertical clearance of less than 6 cm. The vertical clearance is still more preferably less than 3 cm.

The present invention in yet another aspect relates to a method of unloading a wafer-shaped article from a process chamber, comprising moving a robot arm comprising a holder mounted at a distal end of the robot arm so as to cause the holder to pass horizontally into a process chamber through a lateral opening in a process chamber, displacing the holder vertically relative to the distal end of the robot arm so as to bring the holder to an unloading position, positioning a wafer-shaped article on the holder at the unloading position, and withdrawing the wafer-shaped article from the process chamber by displacing the holder vertically relative to the distal end of the robot arm and by moving the robot arm so as to cause the holder to pass horizontally out of the process chamber through the lateral opening.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 is perspective view from above of an end effector utilized in one embodiment of an apparatus according to the present invention, with a wafer positioned thereon;

FIG. 2 a perspective view from below of the configuration depicted in FIG. 1;

FIG. 3 is a view corresponding to that of FIG. 1, with the holder displaced vertically relative to the distal end of the robot arm;

FIG. 4 a perspective view from below of the configuration depicted in FIG. 3;

FIG. 5 is a fragmentary side view showing in greater detail the linkage in the configuration of FIGS. 3 and 4;

FIG. 6 is a fragmentary side view showing in greater detail the linkage in the configuration of FIGS. 1 and 2;

FIG. 7 is a schematic side view of the effector arm in the configuration depicted in FIGS. 1 and 2;

FIG. 8 is a schematic side view of the effector arm in the configuration depicted in FIGS. 3 and 4;

FIG. 9 is perspective view from below of an end effector utilized in another embodiment of an apparatus according to the present invention, with a wafer positioned thereon;

FIG. 10 is a view corresponding to that of FIG. 9, with the holder displaced vertically relative to the distal end of the robot arm;

FIG. 11 is a side view of the configuration depicted in FIG. 9;

FIG. 12 is a side view of the configuration depicted in FIG. 10;

FIG. 13 shows an apparatus according to the embodiment of FIGS. 9-12 after having introduced a wafer into a closed process chamber; and

FIG. 14 shows a subsequent step to that illustrated in FIG. 13, after the wafer has been displaced vertically relative to the robot arm.

### DETAILED DESCRIPTION OF PREFERRED EMBODIMENTS

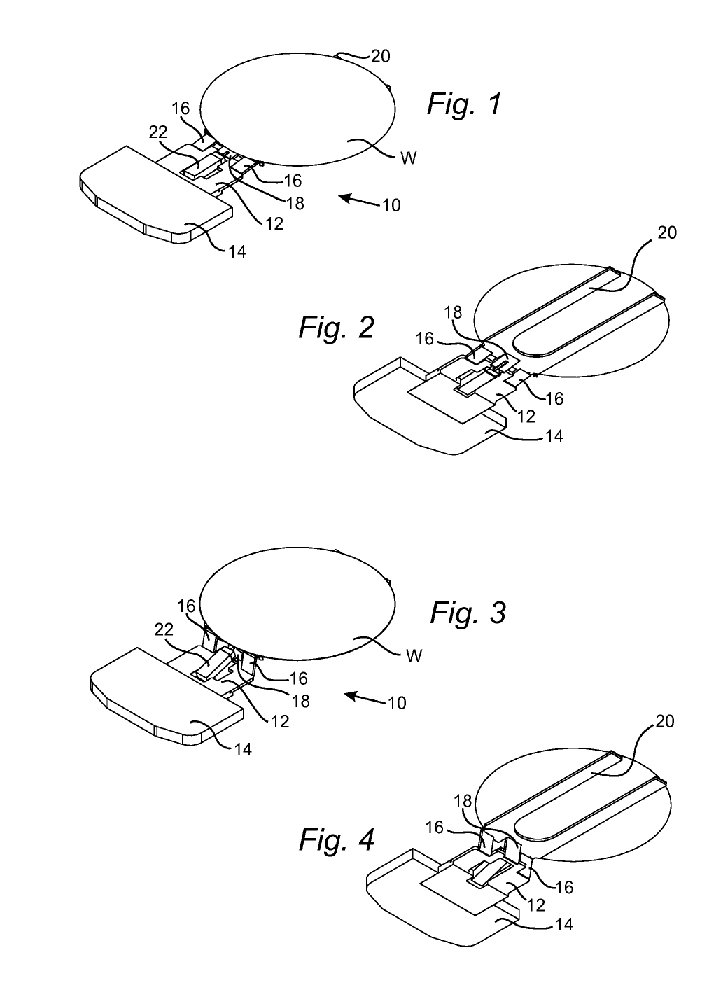

Referring now to FIG. 1, an embodiment of an apparatus for transporting wafer-shaped articles according to the invention comprises an end effector 10 that includes the distal end 12 of a robot arm 14, a holder 20 that is holding a semiconductor wafer W, a parallelogram linkage comprising side links 16 and middle link 18 that interconnects the distal end 12 with the holder 20, and a pneumatic cylinder 22 mounted on the distal end 12 and having an extensible and retractable shaft connected to the middle link 18.

As is shown in FIG. 2, the holder 20 of this embodiment is generally shaped like a tuning fork, and is if the “edge contact only” type as described for example in U.S. Pat. Nos. 6,100,677 and 6,491,330, although other types of holders may also be used. Links 16 and 18 form a parallelogram linkage, with each link being pivotably mounted at its proximal end to the distal end 12 of robot arm 14, and pivotably mounted at its distal end to the holder 22. The extensible and retractable shaft of pneumatic cylinder 22 is pivotably mounted to middle link 18 at a point closer to the distal pivot of link 18 than to the proximal pivot thereof. Pneumatic cylinder is itself pivotably mounted at its proximal end to the distal end 12 of robot arm 14.

Consequently, when the shaft of pneumatic cylinder 22 is retracted, as shown in FIGS. 3 and 4, it lifts up from the distal end 12 somewhat, and also lifts up the middle link 18. This in turn causes the holder 20 to be displaced vertically upwardly, and the side links 16 follow that movement and ensure that the holder 20 and hence the wafer W retain their same angular orientation (in this case horizontal) as the holder is moved upwardly.

The semiconductor wafer W held by holder 20 is for example a silicon wafer whose diameter is 300 mm. 300 mm wafers are a standard size in the semiconductor industry, and the corresponding thickness of such wafers is about 775 micron. The holder 20 in this embodiment is therefore designed to hold wafers of that diameter and thickness. However, the holder 20 may instead be configured to hold wafers of other diameters and thicknesses, for example wafers of 200 mm diameter and 726 micron thickness, or wafers of 450 mm diameter and 925 micron thickness.

The linkage in this embodiment is formed by three links, with the middle link 18 being a drive link and the side links 16 follower links. Alternatively, a linkage with only two links may be used, with one link being the drive link and the other link being the follower, in which case the proximal and distal pivot points of the two links are preferably parallel to and offset from one another, rather than being aligned as with the side links 16.

Other types of linkages may be used to interconnect the distal end of the robot arm with the holder, provided that such linkage is capable of displacing the holder vertically relative to the robot arm and does not cause the end effector to become too tall in the retracted position of the holder, as will be described herein-below. For example, a set of telescoping members connected at one side to the holder and at the opposite side to the distal end of the robot arm could be used.

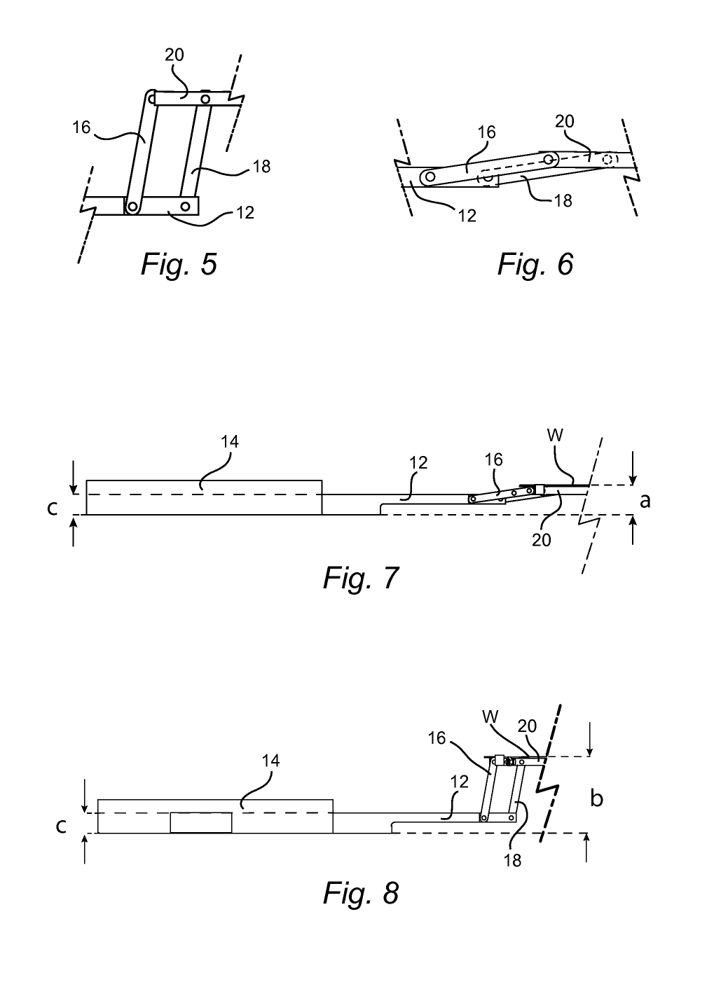

FIGS. 5 and 6 highlight the structure of the parallelogram linkage utilized in the embodiment of FIGS. 1-4. As is shown in those figures, the linkage permits the holder 20 to be raised substantially when in the unloading and loading position illustrated in FIG. 5. On the other hand, when the holder 20 is retracted as shown in FIG. 6, the aspect ratio of the effector arm is quite low, and the effector arm may thereby pass through even very narrow openings formed in a process chamber wall.

For example, as shown in FIGS. 7 and 8, the end effector assembly will have a total vertical extent “a” when the holder is retracted relative to the distal end 12 of robot arm 14 (FIG. 7). However, when holder is displaced vertically relative to the distal end 12 of robot arm 14, the magnitude of the vertical extent is increased to “b.” In this example, the extent “b” is approximately 2.6 times the extent “a”. More generally, “b” is preferably at least 1.5 times “a”, more preferably at least twice “a” and most preferably at least 2.5 times “a”. The difference between “b” and “a” is a measure of how far the wafer W has been displaced vertically, which in this case is about 26 mm for a 300 mm diameter wafer. In practice, the end effector can preferably effect a vertical displacement of the holder arm relative to the robot arm by at least 10 mm, preferably at least 20 mm, and more preferably at least 25 mm.

FIGS. 7 and 8 also illustrate that the thickness of distal end 12 is “c”, which in this embodiment is about 11 mm, whereas the distance “b” in this embodiment is about 42 mm and the distance “a” in this embodiment is about 16 mm. Assuming a 300 mm wafer, the aspect ratio of the end effector of this embodiment is approximately 0.05 in the FIG. 7 configuration and approximately 0.14 in the FIG. 8 configuration.

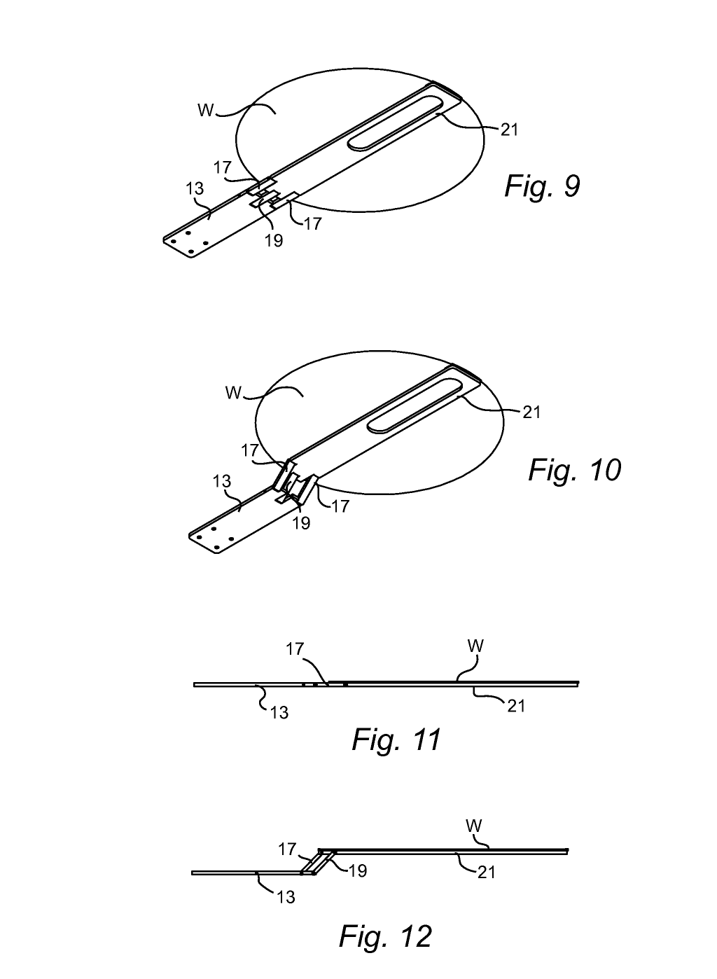

Turning now to FIGS. 9-12, the end effector according to the embodiment of those Figures provides an even smaller holder 21, and a linkage composed of links 17, 19 that together with distal end 13 provides an even smaller aspect ratio than in the previous embodiment. Nevertheless, as is evident from a comparison of FIG. 9 to FIG. 10 and FIG. 11 to FIG. 12, the linkage of this embodiment still permits displacing the holder 21 and wafer W vertically a substantial distance relative to distal end 13.

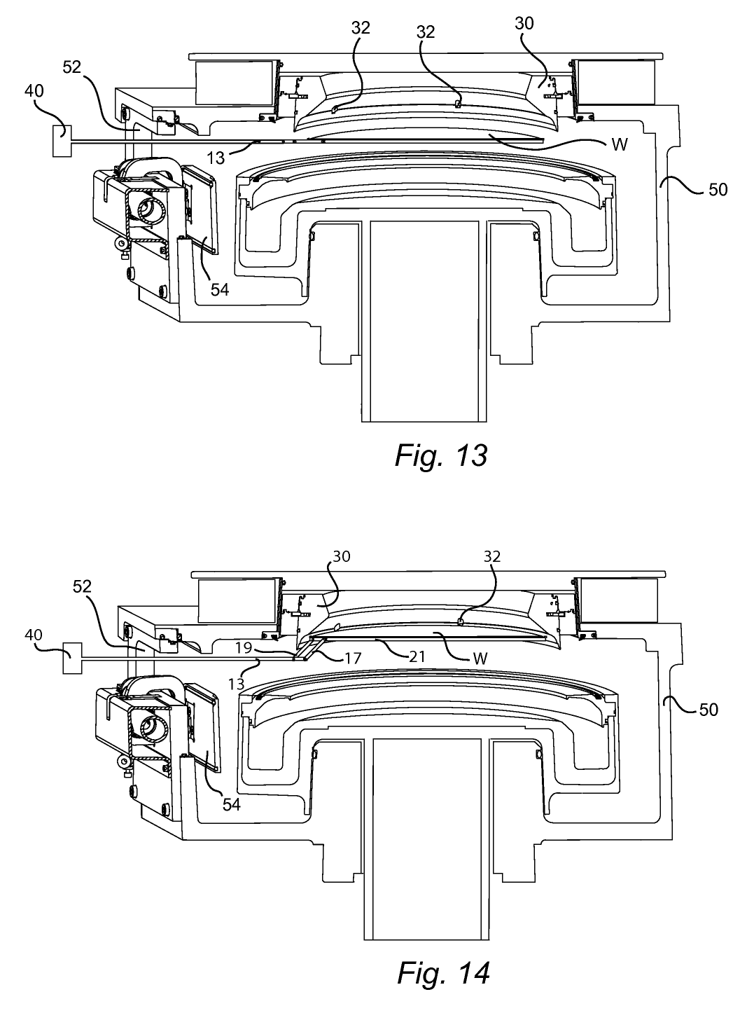

In FIGS. 13 and 14, the apparatus of the embodiment of FIGS. 9-12 is shown in use, loading a wafer W onto a spin chuck inside of a closed process chamber. In particular, the spin chuck 30 and process chamber 50 illustrated in FIGS. 13 and 14 are as described more fully in commonly-owned copending U.S. patent application Ser. No. 13/276,940 filed Oct. 19, 2011. Spin chuck 30 is this embodiment is of the magnetic rotor type, and a wafer W is positioned on chuck 30 via downwardly depending pins 32 such that the wafer hangs down from the chuck.

In FIG. 13, the door 54 covering opening 52 of chamber 50 has been opened, and a wafer transport robot depicted schematically at 40 has moved its arm including distal portion 13 into the chamber 50, such that wafer W is positioned beneath chuck 30. Next, as shown in FIG. 14, the powered actuator, such as a pneumatic cylinder as described previously, is actuated so as the raise the holder 21 relative to the distal end 13 of the robot arm, via links 17, 19, to a loading position in which the eccentric pins 32 can be rotated into engagement with the edge of wafer W.

Unloading of the wafer W from chuck 30 is effected by performing the above-described sequence of operations in reverse.

The apparatus and method of the invention may of course also be used in a spin chuck in which the wafer is held by pins that project upwardly from the chuck. In that case, the linkage is configured so as to displace the holder vertically downwwardly in relation to the robot arm, rather than upwardly.

Although in FIGS. 13 and 14 the distal end 13 of the robot arm is positioned inside chamber 50, it may instead, during loading and unloading of a wafer, depending upon the particular configuration of the chamber and the end effector, be positioned entirely outside the chamber or be positioned partly inside and partly outside the chamber.

What is claimed is:

1. An apparatus for transporting a wafer-shaped article, comprising a holder configured to hold a wafer-shaped article of a predetermined diameter, a robot arm that is horizontally movable, and a linkage interconnecting a distal end of said robot arm and said holder, wherein said holder is vertically movable relative to said distal end of said robot arm via said linkage from a retracted position to an extended position.

2. The apparatus according to claim 1, wherein said distal end of said robot arm, said holder and said linkage collectively have a first vertical extent in said retracted position and a second vertical extent in said extended position, said second vertical extent being at least twice that of said first extent.

3. The apparatus according to claim 1, wherein said holder and said linkage constitute an end effector of a wafer transport robot.

4. The apparatus according to claim 3, wherein said end effector fits through an opening whose vertical clearance is less than 6 cm.

5. The apparatus according to claim 1, wherein said linkage is a parallelogram linkage comprising at least two links.

6. The apparatus according to claim 5, further comprising a powered actuating element engaging at least one of said at least two links, and operable to pivot said link about one of its pivot pins so as to cause said holder to move from a collapsed entry position to an extended loading and unloading position.

7. The apparatus according to claim 1, wherein said powered actuating element comprises a pneumatic cylinder.

8. The apparatus according to claim 6, wherein said powered actuating element is operable to move said holder vertically while said distal end of said robot arm remains stationary.

9. The apparatus according to claim 1, wherein said holder is designed to hold a wafer-shaped article by edge contact only.

10. The apparatus according to claim 1, wherein said holder is configured to hold a wafer-shaped article of a predetermined thickness, and wherein said linkage permits said holder to be moved vertically relative to said distal end of said robot arm by a distance that is at least 15 times greater than the predetermined thickness of the wafer-shaped article.

11. A method of transporting a wafer-shaped article, comprising positioning a wafer-shaped article on a holder of a robot arm, moving the robot arm so as to cause the holder to pass horizontally through a lateral opening in a process chamber, and displacing the holder vertically relative to the robot arm so as to bring the wafer-shaped article to a loading and unloading position.

12. The method according to claim 11, wherein said displacing is effected by a linkage interconnecting the holder and a distal end of the robot arm.

13. The method according to claim 12, wherein a powered actuating element mounted on said robot arm acts on said linkage to effect said displacing.

14. The method according to claim 11, wherein the lateral opening is greater than 30 cm in width and has a vertical clearance of less than 6 cm.

15. A method of unloading a wafer-shaped article from a process chamber, comprising moving a robot arm comprising a holder mounted at a distal end of the robot arm so as to cause the holder to pass horizontally into a process chamber through a lateral opening in a process chamber, displacing the holder vertically relative to the distal end of the robot arm so as to bring the holder to an unloading position, positioning a wafer-shaped article on the holder at the unloading position, and withdrawing the wafer-shaped article from the process chamber by displacing the holder vertically relative to the distal end of the robot arm and by moving the robot arm so as to cause the holder to pass horizontally out of the process chamber through the lateral opening.
